(19) United States
(12) Patent Application Publication
(10) Pub. No.: US 2026/0176736 A1
(43) Pub. Date: Jun. 25, 2026

(54) POROUS MEDIA EVAPORATOR

(71) Applicant: Applied Materials, Inc., Santa Clara, CA (US)

(72) Inventors: Terry Bluck, Santa Clara, CA (US); David Masayuki Ishikawa, Santa Clara, CA (US); Kenneth Moyers, Santa Clara, CA (US); Prasanna Kalleshwara Buddappa Ramachandrappa, Santa Clara, CA (US); Sambhu Kundu, Santa Clara, CA (US); Visweswaren Sivaramakrishnan, Santa Clara, CA (US)

(21) Appl. No.: 19/124,753

(22) PCT Filed: Oct. 26, 2023
(86) PCT No.: PCT/US2023/036015

§ 371 Date: Apr. 25, 2025

Related U.S. Application Data
(60) Provisional application No. 63/381,466, filed on Oct. 28, 2022.

(51) Int. Cl. C23C 14/04; C23C 14/56

(52) U.S. Cl. CPC C23C 14/042; C23C 14/562

(57) ABSTRACT

A method and apparatus for an evaporator assembly are provided. The evaporator assembly includes an evaporator body, a coating basin, and a porous media. The evaporator body includes an evaporator sidewall, an evaporator volume defined by the evaporator sidewall, and an opening defined by the evaporator sidewall. The coating material basin includes a basin sidewall, a coating material volume defined by the basin sidewall, and a coating material bath disposed in the coating material volume. The porous media is partially disposed in the coating material bath and partially disposed within the evaporator volume.

### TECHNICAL FIELD

The present disclosure generally relates to an evaporation system. More particularly, the present disclosure generally relates to a thermal evaporator design, which provides a uniform evaporation rate at relatively low temperatures.

### BACKGROUND

Processing of flexible substrates, such as plastic films or foils, is in high demand in the packaging industry, semiconductor industry, and other industries. Processing can include coating of a flexible substrate with a chosen material, such as a metal. The economical production of these coatings is limited by the thickness uniformity necessary for the product, the reactivity of the coating materials, the cost of the coating materials, and the deposition rate of the coating materials. The most demanding applications generally involve deposition in a vacuum chamber for precise control of the coating thickness and the optimum optical properties. The high capital cost of vacuum coating equipment necessitates a high throughput of coated area for large-scale commercial applications. The coated area per unit time is typically proportional to the coated substrate width and the vacuum deposition rate of the coating material.

A deposition process that can utilize a large vacuum chamber has tremendous economic advantages. Vacuum coating chambers, substrate treating and handling equipment, and pumping capacity, increase in cost less than linearly with chamber size. Therefore, the most economical process for a fixed deposition rate and coating design will utilize the largest substrate available. A larger substrate can generally be fabricated into discrete parts after the coating process is complete. In the case of products manufactured from a continuous web, the web is slit or sheet cut to either a final product dimension or a narrower web suitable for the subsequent manufacturing operations.

One technique used for deposition is thermal evaporation. Thermal evaporation takes place when a source material is heated in an open crucible within a vacuum chamber when a temperature is reached such that there is a sufficient vapor flux from the source for condensation on a cooler substrate. The source material can be heated indirectly by heating the crucible, or directly by a high current electron beam directed into the source material confined by the crucible. Thermal evaporation typically takes place at high temperatures, which can lead to high thermal loads on the substrate being processed. These high thermal loads can damage the substrate. One method for reducing thermal load includes cooling the crucible through radiative cooling. However, radiative cooling is typically very slow, which can lead to significant chamber downtime and an increase in cost of ownership.

In addition, current thermal evaporator designs, which use external heaters can suffer from radiative heat loss, which can lead to increased power consumption to achieve targeted temperatures.

Thus, there is a need for apparatus and methods for reducing the thermal load on substrates during thermal evaporation processes.

### SUMMARY

The present disclosure generally relates to an evaporation system for providing a gas for a reactive deposition process. More particularly, the present disclosure generally relates to a thermal evaporator design, which provides a uniform evaporation rate at relatively low temperatures.

In one aspect, an evaporator assembly is provided. The evaporator assembly includes an evaporator body, a coating basin, and a porous media. The evaporator body includes an evaporator sidewall, an evaporator volume defined by the evaporator sidewall, and an opening defined by the evaporator sidewall. The coating material basin includes a basin sidewall, a coating material volume defined by the basin sidewall, and a coating material bath disposed in the coating material volume. The porous media is partially disposed in the coating material bath and partially disposed within the evaporator volume.

In another aspect, an evaporation system is provided. The evaporation system includes one or more evaporation assemblies. Each of the one or more evaporation assemblies includes an evaporator body, a coating material basin, and a porous media. The evaporation body includes an evaporator sidewall, an evaporator volume defined by the evaporator sidewall, and an opening defined by the evaporator sidewall. The coating material basin includes a basin sidewall, a coating material volume defined by the basin sidewall, and a coating material bath disposed in the coating material volume. The porous media is partially disposed in the coating material bath and partially disposed within the evaporator volume.

In another aspect, a method of coating a substrate is provided. The method includes providing a substrate to an evaporation system; feeding a coating material into an evaporator; heating a porous media of the evaporator; absorbing the coating material into the porous media; evaporating the coating material to form a coating material vapor; and coating the substrate with the coating material vapor.

### BRIEF DESCRIPTION OF THE DRAWINGS

So that the manner in which the recited features of the present disclosure can be understood in detail, a more particular description of the aspects, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a schematic side view of an evaporation system having one or more cylindrical evaporation assemblies in accordance with one or more implementations of the present disclosure.

FIG. 2 illustrates a schematic perspective view of a cylindrical evaporation assembly in accordance with one or more implementations of the present disclosure.

FIG. 3 illustrates a flow chart of a method of coating a substrate in accordance with one or more implementations of the present disclosure.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Vacuum web coating for anode pre-lithiation and solid metal anode deposition generally involves thick (e.g., three to twenty micron) metallic (e.g., lithium) deposition on single-side-coated or double-side-coated flexible substrates, for example, metallic current collectors, such as, copper foil, nickel foil, or metallized plastic web, graphite-coated substrates, or polymer substrates, for example, polyethylene terephthalate (PET) substrates. One technique for deposition is thermal evaporation. Thermal evaporation readily takes place when a source material is heated in an open crucible within a vacuum chamber when a temperature is reached such that there is a sufficient vapor flux from the source for condensation on a cooler substrate. The source material can be heated indirectly by heating the crucible, or directly by a high current electron beam directed into the source material confined by the crucible.

Conventional evaporator systems often involve high temperatures (e.g., approximately 200 to 1500 degrees Celsius) to evaporate, thus placing a high thermal load on the processed web or substrate. Conventional evaporator systems, which use cooling drums also place higher tension on the web (e.g., 200 N to 800 N) to increase contact pressure on the cooling drum. In addition, conventional evaporator systems suffer from high radiative heat load due to the large surface area of the evaporator body at close proximity to the substrate. In addition, conventional evaporator system often use crucibles with external heaters. These external heaters can increase the combined radiative and condensation heat load further increasing thermal load.

The increased thermal loads and contact pressures can have several drawbacks. For example, the increased thermal loads and contact pressures can lead to wrinkling of the processed web, can lead to tearing of the web during processing, and can affect the final product after coating. Further, current evaporator systems are often very sensitive to the inclination angle of deposition, which can present additional challenges when deposition takes place over a cooling drum. In addition, some conventional evaporator systems include complex two body designs, which are very susceptible to leaks in a hot environment thus increasing material costs.

The thermal evaporator described herein includes a porous media evaporator design, which can evaporate material for deposition at high-rates with significantly lower heat loads for evaporation. The porous media evaporator design of the present disclosure eliminates the external crucible heater found in currently available evaporator designs. Elimination of the external crucible heater reduces power consumption and decreases the heat load on the web substrate. The porous media evaporator design of the present disclosure minimizes heat loss. The porous media evaporator design is not sensitive to the inclination angle relative to the substrate. In addition, due to the lower thermal heat load of the porous media evaporator design, wrinkling of the web substrate is significantly reduced.

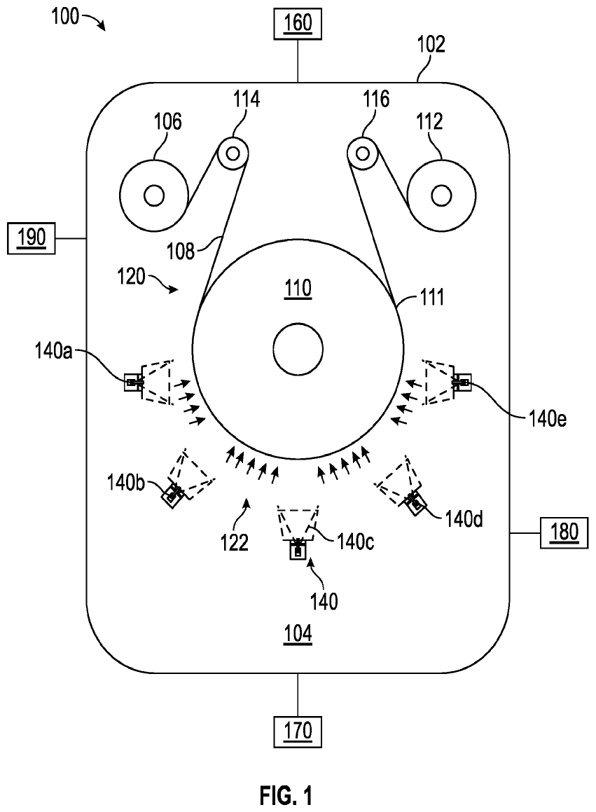

FIG. 1 illustrates a schematic side view of an evaporation system 100 including one or more porous media thermal evaporation assemblies 140a-140e (collectively 140), in accordance with one or more implementations of the present disclosure. The evaporation system 100 can be a roll-to-roll system adapted for depositing coatings on web materials, for example, for depositing metal containing film stacks according to the implementations described. In one example, the evaporation system 100 can be used for depositing metals or metal alloys. For example, the evaporation system 100 and the porous media thermal evaporation assemblies 140 can be used for depositing metals or metal alloys. Examples of metal and metal alloys include but are not limited to alkali metals (e.g., lithium or sodium), selenium, magnesium, zinc, cadmium, aluminum, gallium, indium, thallium, tin, lead, antimony, bismuth, tellurium, alkali earth metals, silver, or a combination thereof. These metals or metal alloys can be used for manufacturing energy storage devices, and particularly for film stacks for lithium-containing anode structures. The evaporation system 100 includes a chamber body 102 that defines a common processing environment 104 in which some or all of the processing actions for depositing coatings on web materials can be performed. In one example, the common processing environment 104 is operable as a vacuum environment. In another example, the common processing environment 104 is operable as an inert gas environment. In some examples, the common processing environment 104 can be maintained at a process pressure of 1×10⁻³ mbar or below, for example, 1×10⁻⁴ mbar or below.

The evaporation system 100 is constituted as a roll-to-roll system including an unwinding reel 106 for supplying a continuous flexible substrate 108 or web, a coating drum 110 over which the continuous flexible substrate 108 is processed, and a winding reel 112 for collecting the continuous flexible substrate 108 after processing. The coating drum 110 includes a deposition surface 111 over which the continuous flexible substrate 108 travels while material is deposited onto the continuous flexible substrate 108. The evaporation system 100 can further include one or more auxiliary transfer reels 114, 116 positioned between the unwinding reel 106, the coating drum 110, and the winding reel 112. According to one aspect, at least one of the one or more auxiliary transfer reels 114, 116, the unwinding reel 106, the coating drum 110, and the winding reel 112 can be driven and rotated by a motor. In one example, the motor is a stepper motor. Although the unwinding reel 106, the coating drum 110, and the winding reel 112 are shown as positioned in the common processing environment 104, it should be understood that the unwinding reel 106 and the winding reel 112 can be positioned in separate chambers or modules. For example, at least one of the unwinding reel 106 can be positioned in an unwinding module, the coating drum 110 can be positioned in a processing module, and the winding reel 112 can be positioned in an unwinding module.

The unwinding reel 106, the coating drum 110, and the winding reel 112 can be individually temperature controlled. For example, the unwinding reel 106, the coating drum 110, and the winding reel 112 can be individually heated using an internal heat source positioned within each reel or an external heat source.

In one implementation, which can be combined with other implementations, the one or more porous media thermal evaporation assemblies 140 can be removably coupled with the containment shield (not shown). In another implementation, which can be combined with other implementations, the one or more porous media thermal evaporation assemblies 140 can be spaced apart from the coating drum 110. The one or more porous media thermal evaporation assemblies 140 are positioned to deliver evaporated coating material onto the continuous flexible substrate 108 as the continuous flexible substrate 108 travels through a deposition zone 120 over the deposition surface 111 of the coating drum 110.

The deposition zone 120 is defined in between the one or more porous media thermal evaporation assemblies 140 and the deposition surface 111 of the coating drum 110. In one implementation, which can be combined with other implementations, the deposition zone 120 provides an isolated processing region within the common processing environment 104 of the chamber body 102. The deposition zone 120 can be minimized and defined to conform to a web, for example, the continuous flexible substrate 108 that is wound on a cylindrical cooling drum, such as the coating drum 110, a planar cooling plate, or in a free span orientation. In one implementation, which can be combined with other implementations, the deposition zone 120 is defined by at least one containment shield disposed between the porous media thermal evaporator assembly 140 and the coating drum 110. The containment shield defines the deposition zone 120 for confinement of the evaporated coating material to be deposited.

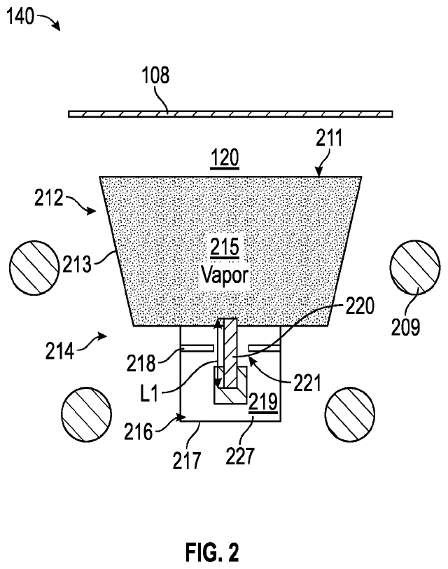

The one or more porous media thermal evaporation assemblies 140 will be described in greater detail with reference to FIG. 2. The one or more porous media thermal evaporation assemblies 140 are positioned to perform one or more processing operations to the continuous flexible substrate 108 or web of material. In one example, as depicted in FIG. 1, the one or more porous media thermal evaporation assemblies 140 are radially disposed about the coating drum 110. In addition, arrangements other than radial are contemplated. In one implementation, which can be combined with other implementations, the one or more porous media thermal evaporation assemblies 140 include a lithium (Li) source. Further, the one or more porous media thermal evaporation assemblies 140 can also include a source of an alloy of two or more metals. The coating material to be deposited can be evaporated, for example, by thermal evaporation techniques.

In operation, the one or more porous media thermal evaporation assemblies 140 emit a plume of evaporated coating material 122, which is drawn to the continuous flexible substrate 108 where a film of deposited material is formed on the continuous flexible substrate 108.

In addition, although five porous media thermal evaporation assemblies 140a-140e are shown in FIG. 1, it should be understood that any number of evaporation assemblies can be used. In addition, the evaporation system 100 can further include one or more additional deposition sources. For example, the one or more deposition sources as described include an electron beam source and additional sources, which can be selected from the group of CVD sources, PECVD sources, and various PVD sources. Exemplary PVD sources include sputtering sources, electron beam evaporation sources, and thermal evaporation sources. In addition, these additional deposition sources can be positioned radially relative to the deposition surface 111 of the coating drum 110.

In one implementation of the present disclosure, which can be combined with other implementations, the evaporation system 100 is configured to process both sides of the continuous flexible substrate 108. For example, additional evaporation assemblies similar to the one or more porous media thermal evaporation assemblies 140 can be positioned to process the opposing side of the continuous flexible substrate 108. Although the evaporation system 100 is configured to process the continuous flexible substrate 108, which is horizontally oriented, the evaporation system 100 can be configured to process substrates positioned in different orientations, for example, the continuous flexible substrate 108 can be vertically oriented. In one implementation of the present disclosure, which can be combined with other implementations, the continuous flexible substrate 108 is a flexible polymer substrate, for example, a polyethylene terephthalate “PET” substrate, a flexible conductive substrate, for example a copper foil substrate, or a combination of both. In one implementation of the present disclosure, which can be combined with other implementations, the continuous flexible substrate 108 includes a conductive substrate with one or more layers formed thereon. In one implementation of the present disclosure, which can be combined with other implementations, the conductive substrate is a copper substrate.

The evaporation system 100 further includes a gas panel 160. The gas panel 160 uses one or more conduits (not shown) to deliver processing gases to the evaporation system 100. The gas panel 160 can include mass flow controllers and shut-off valves, to control gas pressure and flow rate for each individual gas supplied to the evaporation system 100. Examples of gases that can be delivered by the gas panel 160 include, but are not limited to, inert gases for pressure control (e.g., argon), etching chemistries including but not limited to diketones used for in-situ cleaning of the evaporation system 100, and deposition chemistries including but not limited to 1,1,1,2-Tetrafluoroethane or other hydrofluorocarbons and trimethylaluminum, titanium tetrachloride, or other metal organic precursors used for in-situ tens of nanometer thick reactive lithium mixed conductor surface modification.

The evaporation system 100 further includes a system controller 170 operable to control various aspects of the evaporation system 100. The system controller 170 facilitates the control and automation of the evaporation system 100 and can include a central processing unit (CPU), memory, and support circuits (or I/O). Software instructions and data can be coded and stored within the memory for instructing the CPU. The system controller 170 can communicate with one or more of the components of evaporation system 100 via, for example, a system bus. A program (or computer instructions) readable by the system controller 170 determines which tasks are performable on a substrate. In some aspects, the program is software readable by the system controller 170, which can include code for monitoring chamber conditions, including independent temperature control of the one or more porous media thermal evaporation assemblies 140. Although only a single system controller, the system controller 170 is shown, it should be appreciated that multiple system controllers can be used with the aspects described.

The evaporation system 100 may further include a power supply 180 for supplying power to the components of the evaporation system 100. For example, the power supply 180 may be electrically coupled with the one or more heating sources in the porous media thermal evaporator assemblies 140.

The evaporation system 100 may further include a coating material supply source 190 for supplying coating material to each of the porous media thermal evaporator assemblies 140. In one implementation, which can be combined with other implementations, the coating material supply maintains the coating material in liquid form.

In some embodiments, each porous media thermal evaporator assembly 140a-e is spaced from an adjacent porous media thermal evaporator assembly by about 22 to about 26 centimeters. In such embodiments, the coating drum 110 is a gas cushion drum, which is cooled to a range from about-10 degrees Celsius to about 50 degrees Celsius, and a travel speed of the continuous flexible substrate is approximately 2 meters/minute, which provides a line speed cooling time between the nozzles of adjacent porous media thermal evaporator assemblies 140a-e of about 12 to 13 seconds.

FIG. 2 illustrates a schematic, cross-section of a porous media evaporator assembly 140. The porous media evaporator assembly 140 includes a porous media evaporator 214. The porous media evaporator 214 is designed to hold and evaporate a coating material to be evaporated, for example, a metal or metal alloy. The porous media evaporator 214 includes an evaporator body 212, a coating material basin 216, and one or more heaters 209. The evaporator body 212 includes an evaporator sidewall 213, and the coating material basin 216 includes a basin sidewall 217. The evaporator sidewall 213 defines an evaporator volume 215 and an evaporator opening 211. The basin sidewall 217 defines a coating material volume 219. A porous media 220 and a coating material bath 227 are disposed within the coating material basin 216. The coating material bath 227 is configured to receive the coating material from the coating material source 190 and to contain the coating material within the coating material basin 216. A basin isolator 218 isolates the coating material volume 219 from the evaporator volume 215. The basin isolator 218 blocks thermal radiation from the coating material basin 216 from expending the thermal budget of the substrate 108.

The porous media 220 is partially submerged in the coating material bath 227. The porous media 220 extends out of the coating material bath 227 and the coating material basin 216 via a media opening 221 in the basin isolator 218. The porous media 220 extends partially into the evaporator volume 215.

In some embodiments, the porous media 220 may include a ferrous material, e.g., a sintered porous stainless steel, a woven pleated stainless steel, tungsten (W), titanium (Ti), tantalum (TA), or combinations thereof. In other embodiments, the porous media may be a porous mesh. In still other embodiments, the porous media 220 may include a porous cylinder disposed around the porous media 220. In still other embodiments, the porous media 220 may be an array of tubular media. The porous cylinder may include micron-sized porous holes in a linear or spiral pattern. The porous holes may be about 20 μm to about 100 μm in diameter. The pore size of the porous media 220 is between about 1 μm to about 500 μm. In various embodiments, a portion of the porous media 220 that is exposed (e.g., not submerged in the coating material bath 227) has a surface area at least 25% greater than the surface area of a portion of the porous media 220 that is submerged in the coating material bath 227.

The heaters 209 are positioned around the porous media evaporator 214. The heaters 209 are configured to heat the porous media evaporator 214 to a temperature of about 150° C. to 400° C., such as about 186° C. to about 350° C.

A feed line (not shown) feeds the coating material to the coating material bath 227. The coating material is metered in to the coating material bath 227 at a rate of up to about 500 cc/min. The porous media 220 is configured to absorb the coating material through capillary forces. As the coating material is absorbed into the porous media 220, the coating material rises up the porous media 220 and out of the coating material basin 216. In some embodiments, the porous media 220 may be heated to a temperature of about 150° C. to 400° C., such as about 186° C. to about 350° C. to maintain the melt temperature of the coating material. In other embodiments, the porous media 220 is heated from the coating material bath 227. The coating material evaporates as it travels up the porous media 220, emitting a coating material vapor into the evaporation volume 215 through a sidewall of the porous media 220.

The porous media 220 has a length L1 of about 25 mm to about 100 mm. The porous media may be an array of rods, an array of cylinders, a cylinder, a rectangular column, or an array of rectangular columns. The rods may have a diameter of about 10 mm to about 20 mm. The cylinders may have an outer diameter of about 10 mm to about 25 mm and a cylinder wall thickness of about 1 mm to about 6 mm. The array of rectangular columns may have square cross-section with a width of about 10 mm to about 25 mm and a rectangular wall thickness of about 1 mm to about 6 mm. The porous media 220 creates a large surface area for evaporation of the coating material. Thus, a small amount of coating material is capable of creating a large amount of coating material vapor.

The radiative heat incident to the substrate 108 is related to the heat source by a view factor of T⁴, where T is the temperature of the heat source. The surface area of the porous media 220, coupled with the small amount of coating material being melted within the porous media 220, enables a reduction in the temperature of the porous media 220 and, therefore, a reduction in the radiative heat incident to the substrate 108.

A reduction in the size of the coating material bath 227 as compared to an open bath evaporator enables a reduction in the amount of coating material used in the coating process, and a reduction in cool down time of the system after processing due to the reduced volume of coating material to be cooled. Further, the reduction in the size of the coating material bath 227 enables more efficient replenishment of the coating material bath 227 during the coating process.

In some embodiments, the evaporator opening 211 includes one or more nozzles. The nozzles may enable more precise deposition of the coating material on the substrate 108. In order to prevent the nozzles from clogging during the deposition process, the nozzles must be heated to a temperature greater than the temperature of the evaporator. The reduction in the radiative heat of the porous media evaporator 214 enables the reduction in the radiative heat of the nozzles, thus enabling a decrease in the thermal budget expended by the substrate 108 during processing.

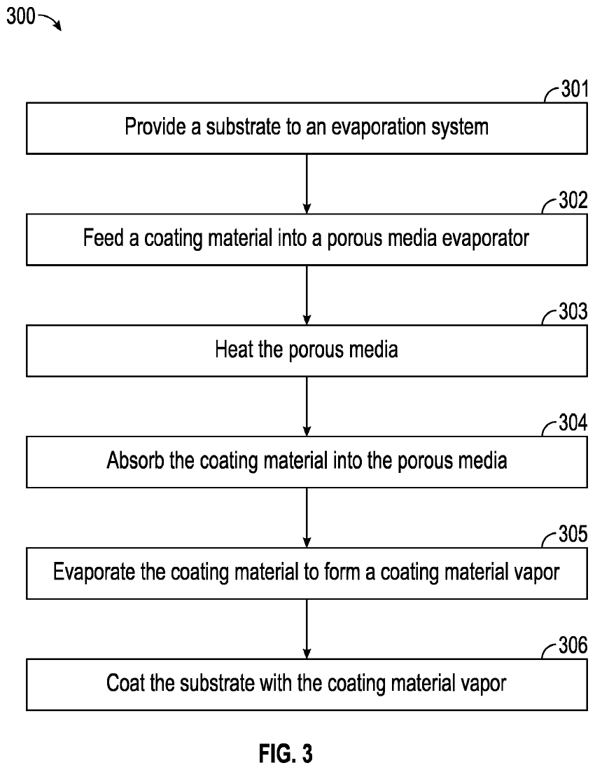

FIG. 3 illustrates a flow chart of a method 300 of coating a substrate 108. The method 300 begins at operation 301, where a substrate 108 is provided to an evaporation system 100. In various embodiments, the evaporation system 100 includes an unwinding reel 106, a coating drum 110, a winding reel 112, a coating material supply source 190, and a power supply 180. The substrate 108 travels through the evaporation system 100 via the unwinding reel 106, the coating drum 110, and the winding reel 112.

At operation 302, a coating material is fed into a porous media evaporator 214. The coating material is fed to a coating material bath 227 disposed in the porous media evaporator 214 from the coating material supply source 190. The porous media evaporator 214 is disposed within the evaporation system 100. The porous media evaporator 214 includes a porous media 220, an evaporator volume 215 defined by an evaporator body 212, and a coating material volume 219 defined by a coating material basin 216. The coating material bath is disposed in the coating material volume 219. The porous media 220 has a porosity of about 2 μm to about 500 μm. The coating material is metered into the gap 226 at up to about 500 cc/min.

At operation 303, the porous media 220 is heated. The porous media 220 is heated to a temperature of about 150° C. to 400° C., such as about 186° C. to about 350° C. to maintain the melt temperature of the coating material. In some embodiments, the porous media 220 is heated using a heater. In other embodiments, the porous media 220 is heated from the coating material bath 227.

At operation 304, the porous media 220 absorbs the coating material. The coating material is absorbed into the porous media 220 through capillary forces. The capillary forces move the coating material from the coating material volume 219 to the evaporator volume 215.

At operation 305, the porous media 220 evaporates the coating material to form a coating material vapor. The coating material vapor is emitted from the sidewalls of the porous media 220 into the evaporator volume.

At operation 306, the substrate 108 is coated with the coating material vapor. The thickness of the coating material deposited on the substrate 108 is greater than about 1 μm, such as up to about 20 μm.

In summation, a porous media evaporator is disclosed. The porous media evaporator uses capillary forces to absorb a coating material from a coating material bath and evaporate the coating material into an evaporator volume. The porous media enables a large surface area for the production of a coating material vapor from a small amount of coating material. The reduction in the amount of coating material enables a reduction in the radiative heat from the evaporator, leading to a reduction in the thermal budget expended by the substrate 108. The reduction in the amount of coating material further allows for a decrease in the cool down time of the porous media evaporator and more efficient replenishment of the coating material bath.

According to some implementations, evaporation processes and evaporation apparatus for layer deposition on substrates, for example on flexible substrates, are provided. Thus, flexible substrates can be considered to include among other things films, foils, webs, strips of plastic material, metal, or other materials. Typically, the terms “web,” “foil,” “strip,” “substrate” and the like are used synonymously. According to some implementations, components for evaporation processes, apparatuses for evaporation processes and evaporation processes according to implementations described can be provided for the above-described flexible substrates. However, they can also be provided in conjunction with non-flexible substrates such as glass substrates or the like, which are subject to the reactive deposition process from evaporation sources.

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

1. An evaporator assembly, comprising:
an evaporator body, comprising:
an evaporator sidewall;
an evaporator volume defined by the evaporator sidewall; and
an opening defined by the evaporator sidewall; and
a coating material basin, comprising:
a basin sidewall;
a coating material volume defined by the basin sidewall;
a coating material bath disposed in the coating material volume; and
a porous media partially disposed in the coating material bath and partially disposed within the evaporator volume.

2. The evaporator of claim 1, wherein the porous media has a length of about 25 mm to about 100 mm.

3. The evaporator of claim 1, wherein the porous media has a diameter of about 10 mm to about 25 mm.

4. The evaporator of claim 1, wherein the porous media is configured to absorb a coating material provided to the coating material bath.

5. The evaporator of claim 3, wherein the porous media is configured to absorb a coating material using capillary forces.

6. The evaporator of claim 1, wherein the coating material basin further comprises a basin isolator configured to isolate the coating material volume from the evaporator volume.

7. The evaporator of claim 1, wherein the porous media has a porosity from about 1 μm to about 500 μm.

8. The evaporator of claim 1, wherein the porous media comprises a sintered porous stainless steel, a woven pleated stainless steel, a porous mesh, or an array of tubular media.

9. The evaporator of claim 1, further comprising a porous cylinder disposed around the porous media.

10. The evaporator of claim 1, wherein the porous media includes pores in a linear or spiral pattern.

11. The evaporator of claim 10, wherein the pores have a diameter of about 20 μm to about 100 μm.

12. An evaporation system, comprising:
one or more evaporation assemblies, each of the one or more evaporation assemblies comprising:
an evaporator body, comprising:
an evaporator sidewall;
an evaporator volume defined by the evaporator sidewall; and
an opening defined by the evaporator sidewall; and
a coating material basin, comprising:
a basin sidewall;
a coating material volume defined by the basin sidewall;
a coating material bath disposed in the coating material volume; and
a porous media partially disposed in the coating material bath and partially disposed within the evaporator volume.

13. The evaporation system of claim 12, wherein the porous media comprises a sintered porous stainless steel, a woven pleated stainless steel, a porous mesh, or an array of tubular media.

14. The evaporation system of claim 12, wherein the porous media includes pores in a linear or spiral pattern.

15. The evaporation system of claim 14, wherein the pores have a diameter of about 20 μm to about 100 μm.

16. The evaporation system of claim 12, wherein the porous media has a pore size from about 1 μm to about 500 μm.

17. A method of coating a substrate, comprising:
providing a substrate to an evaporation system;
feeding a coating material into an evaporator;
heating a porous media of the evaporator;
absorbing the coating material into the porous media;
evaporating the coating material to form a coating material vapor; and
coating the substrate with the coating material vapor.

18. The method of claim 17, wherein absorbing the coating material into the porous media is performed via capillary forces.

19. The method of claim 17, further comprising heating the porous media to a temperature of about 186° C. to about 350° C.

20. The method of claim 17, wherein the porous media has a porosity from about 1 μm to about 500 μm.
